(19) United States
(12) Patent Application Publication
(10) Pub. No.: US 2004/0051541 A1
(43) Pub. Date: Mar. 18, 2004

(54) Contact structure with flexible cable and probe contact assembly using same

(76) Inventors: Yu Zhou, Vernon Hills, IL (US); Gert K.G. Hohenwarter, Monona, WI (US); David Yu, Bloomingdale, IL (US); Robert Edward Aldaz, Carol Stream, IL (US); Theodore A. Khoury, Evanston, IL (US)

Correspondence Address: MURAMATSU & ASSOCIATES, Suite 225, 7700 Irvine Center Drive, Irvine, CA, 92618, US

(21) Appl. No.: 10/234,299

(22) Filed: Sep. 4, 2002

(51) Int. Cl. G01R 31/02

(52) U.S. Cl. 324/754

(57) ABSTRACT

A contact structure having contactors formed on a flexible cable establishes electrical connection with contact targets. The contact structure includes a probe card having a plurality of contact pads and signal patterns, a plurality of contactors mounted on a contactor carrier, a flexible cable having a plurality of signal patterns for transmitting electrical signals therethrough. A first end of the flexible cable has a small pitch of the signal patterns while a second end of the flexible cable has a pitch of signal lines which is substantially larger than that of the first end. The first end of the flexible cable is connected to the contactors and the second end of the flexible cable is connected to the probe card.

### FIELD OF THE INVENTION

This invention relates to a contact structure to establish electrical connection with contact targets such as contact pads on semiconductor devices, and more particularly, to a contact structure formed with use of a flexible cable for use with a probe contact assembly to test semiconductor wafers, IC chips and the like, with high speed, high density and low cost.

### BACKGROUND OF THE INVENTION

In testing high density and high speed electrical devices such as LSI and VLSI circuits, a high performance contact structure provided on a probe card must be used. A contact structure is basically formed of a contact substrate (space transformer) having a large number of contactors or probe elements. The contact substrate is mounted on a probe card for testing LSI and VLSI chips, semiconductor wafers, burn-in of semiconductor wafers and dice, testing and burn-in of packaged semiconductor devices, printed circuit boards and the like.

In the case where semiconductor devices to be tested are in the form of a semiconductor wafer, a semiconductor test system such as an IC tester is usually connected to a substrate handler, such as an automatic wafer prober, to automatically test the semiconductor wafer. Such an example is shown in FIG. 1 in which a semiconductor test system has a test head 100 which is ordinarily in a separate housing and electrically connected to the test system with a bundle of cables 110. The test head 100 and a substrate handler 400 are mechanically as well as electrically connected with one another with the aid of a manipulator 500 which is driven by a motor 510. The semiconductor wafers to be tested are automatically provided to a test position of the test head 100 by the substrate handler 400.

On the test head 100, the semiconductor wafer to be tested is provided with test signals generated by the semiconductor test system. The resultant output signals from the semiconductor wafer under test (IC circuits formed on the semiconductor wafer) are transmitted to the semiconductor test system. In the semiconductor test system, the output signals are compared with expected data to determine whether the IC circuits on the semiconductor wafer function correctly or not.

In FIG. 1, the test head 100 and the substrate handler 400 are connected through an interface component 140 consisting of a performance board 120 (shown in FIG. 2) which is a printed circuit board having electric circuit connections unique to a test head's electrical footprint, coaxial cables, pogo-pins and connectors (test fixture). In FIG. 2, the test head 100 includes a large number of printed circuit boards 150 which correspond to the number of test channels (test pins) of the semiconductor test system. Each of the printed circuit boards 150 has a connector 160 to receive a corresponding contact terminal 121 of the performance board 120. A pogo-pin block (test fixture) 130 is mounted on the performance board 120 to accurately determine the contact position relative to the substrate handler 400. The pogo-pin block (test fixture) 130 has a large number of contact pins 141, such as ZIF connectors or pogo-pins, connected to contact terminals 121, through coaxial cables 124.

As shown in FIG. 2, the test head 100 is placed over the substrate handler 400 and mechanically and electrically connected to the substrate handler through the interface component 140. In the substrate handler 400, a semiconductor wafer 300 to be tested is mounted on a chuck 180. In this example, a probe card 200 is provided above the semiconductor wafer 300 to be tested. The probe card 200 has a large number of probe contactors (such as cantilevers or needles) 190 to contact with contact targets such as circuit terminals or contact pads in the IC circuit on the semiconductor wafer 300 under test.

Electrical terminals or contact pads of the probe card 200 are electrically connected to the contact pins (pogo-pins) 141 provided on the pogo-pin block 130. The contact pins 141 are also connected to the contact terminals 121 of the performance board 120 with the coaxial cables 124 where each contact terminal 121 is connected to the printed circuit board 150 of the test head 100. Further, the printed circuit boards 150 are connected to the semiconductor test system through the cable 110 having, for example, several hundreds of inner cables.

Under this arrangement, the probe contactors 190 contact the surface (contact targets) of the semiconductor wafer 300 on the chuck 180 to apply test signals to the semiconductor wafer 300 and receive the resultant output signals from the wafer 300. The resultant output signals from the semiconductor wafer 300 under test are compared with the expected data generated by the semiconductor test system to determine whether the IC circuits on the semiconductor wafer 300 performs properly.

FIG. 3 is a cross sectional view showing an example of structure of a probe contact system formed with a pogo-pin block 130, a probe card 60, a space transformer 50, and a contactor carrier 40. Typically, the contactor carrier 40 is provided with a large number of contactors 30. In the example of FIG. 3, the space transformer 50 is utilized to fan-out the small pitch of the contactors 30 on the contactor carrier 40 to a larger pitch of the contact pads 62 on the probe card 60. The space transformer 50 has a large number of inner patterns 52 and 54 to change the space (pitch) of the contactors 30. The space transformer 50 is made of, for example, multi-layers of ceramic, and costly.

Interconnect traces 63 of the probe card 60 fans-out the pitch further so that contact pads 65 of the probe card 60 can contact with pogo-pins 141 of the pogo-pin block 130. FIG. 3 further shows a semiconductor wafer 300 having contact pads 320 thereon as contact targets. The pogo-pin block 130 and probe card 60 in FIG. 3 respectively correspond to the pogo-pin block 130 and probe card 200 in FIG. 2.

The pogo-pin block 130 has a large number of pogo-pins (contact pins) 141 to interface between the probe card 60 and the performance board 120 (FIG. 2). At upper ends of the pogo-pins 141, cables 124 such as coaxial cables are connected to transmits signals to printed circuit boards (pin cards) 150 in the test head 100 in FIG. 2 through the performance board 120.

The probe card 60 has a large number of contact pads (pogo-pin pads) 65 on the upper surface and contact pads 62 on the lower surfaces thereof. The contact pads 62 and 65 are connected through interconnect traces 63 to fan-out the pitch of the contact structure to match the pitch of the pogo-pins 141 on the pogo-pin block 130.

As shown in FIG. 3, the contact carrier 40 is provided with a plurality of contactors 30. The contact carrier 40 is so positioned over the contact targets such as contact pads 320 on a semiconductor wafer 300 to be tested that the contactors 30 establish electric connections with the semiconductor wafer 300 when pressed against the other. Although only two contactors 30 are shown in FIG. 3, a large number, such as several hundreds or several thousands of contactors 30 are aligned on the contact carrier 40 in actual applications such as semiconductor wafer testing.

The contactors 30 in this example have a top contact portion protruding through the top surface of the contactor carrier 40 to electrically connect with the contact pad of the space transformer 50, a body portion that is housed in the via hole of the contactor carrier 40, a spring portion projected from the bottom surface of the contactor carrier 40 and bent to produce a resilient contact force when pressed against the contact target, and a bottom contact portion that establishes electrical contact with the contact targets 320 on the wafer 300. The contactors 30 can be made through a semiconductor production process including, for example, photolithography and electroplating processes on a silicon substrate. Since the contactors 30 can be fabricated in a very small size, such as 50 μm pitch, an operable frequency range of a contact structure or probe card mounting the contactors 30 can be in the range of 2 GHz or higher.

When the semiconductor wafer 300 moves upward, the contactors 30 and the contact targets 320 on the wafer 300 mechanically and electrically contact with each other. Consequently, a signal path is established from the contact target 320 to a test head of the semiconductor test system through the contactor 30 of the contactor carrier 40, pads and interconnect trace 54 of the space transformer 50, contact pads 62, 65, and interconnect trace 63 of the probe card 60, and pogo-pin block 130.

In the foregoing conventional example, a large number of contactors must be used in the semiconductor wafer test, such as from several hundreds to several thousands. Because such a large number of contactors are needed in the contact structure, the resultant contact structure involves high production cost. Since the semiconductor industry is under the continued demands of improving performance per cost, it is also necessary to decrease the test cost using the semiconductor test system. Under the circumstances, there is a need in the industry to incorporate a more simple and economical way to form the contact structure for testing semiconductor wafers or IC chips.

### SUMMARY OF THE INVENTION

Therefore, it is an object of the present invention to provide a contact structure and a probe contact assembly to establish electrical connection with contact targets with low cost and high performance.

It is another object of the present invention to provide a contact structure and a probe contact assembly having a flexible cable with wide-pitched signal lines on one end and narrow-pitched signal lines on the other end for space transforming as well as for establishing electrical communication with contact targets with high frequency range, density and low cost.

It is a further object of the present invention to provide a contact structure and a probe contact assembly having a flexible cable and contactors formed at one end of the flexible cable for establishing electrical communication with contact targets with high frequency range, density and low cost.

It is a further object of the present invention to provide a contact structure and a probe contact assembly using a flexible cable for establishing signal paths between contactors and contact pads on a probe card to eliminate a space transformer or fine patterns on the space transformer thereby reducing the cost of the probe contact assembly.

In the present invention, the contact structure includes a probe card having a plurality contact pads, a contactor carrier for mounting a plurality of contactors, and a flexible cable having a plurality of signal lines for transmitting electrical signals therethrough. A first end of the flexible cable has a small pitch of the signal patterns while a second end of the flexible cable has a pitch of signal lines which is substantially larger than that of the first end. The first end of the flexible cable is connected to the contactors and the second end of the flexible cable is connected to the probe card.

In the contact structure of the present invention, each of the contactors is integrally formed with the flexible cable by conductor of the corresponding signal line on the flexible cable. Alternatively, the contactors are produced separately from the flexible cable and attached to the corresponding signal lines on the flexible cable.

Preferably, the contact structure includes a socket to connect the second end of the flexible cable to the probe card. The contact structure further includes an adaptor mounted on the contactor carrier to connect the first end of the flexible cable to the plurality of contactors. An adhesive may be used to connect the first end of the flexible cable to the plurality of contactors.

In another aspect of the present invention, the contact structure includes a conductive elastomer between the probe card and the flexible cable, and an adaptor between the probe card and the contactor carrier on which the flexible cable is bent around to electrically connect the first end of the flexible cable to the plurality of contactors and also to connect the second end of the flexible cable to the probe card through the conductive elastomer.

Further aspect of the present invention is a probe contact assembly for interfacing between semiconductor device under test and a semiconductor test system. The probe contact assembly includes the contact structure noted above in addition to a plurality of flexible cables for connecting the contactors which probe the signals on the semiconductor device under test to the probe card which is connected to the semiconductor test system thereby sending test signals to the semiconductor device under test.

According to the present invention, the contact structure is created with use of flexible flat cables which are available in the market. The contactors are formed at one end of the flexible cable and are mounted on a contactor carrier. The contact structure of the present invention is low cost, reliable and yet achieves high performance. Since the flexible cables connecting the contactors and the pads on the probe card enable to obviate either a space transformer (contact substrate) or fine pitch wiring patterns on the space transformer in the conventional technology, the present invention also contributes to the overall cost reduction and design simplification in the probe contact assembly.

### BRIEF DESCRIPTION OF THE DRAWINGS

FIG. 1 is a schematic diagram showing a structural relationship between a substrate handler and a semiconductor test system having a test head.

FIG. 2 is a diagram showing an example of detailed structure for connecting the test head of the semiconductor test system to the substrate handler.

FIG. 3 is a schematic diagram showing a cross sectional view of an example of a probe contact system using the conventional contact structure for interfacing between the semiconductor device under test and the test head of the semiconductor test system.

FIG. 4 is a schematic diagram showing a cross sectional view of a probe contact assembly using the contact structure of the present invention for interfacing between the semiconductor device under test and the test head of the semiconductor test system.

FIG. 5 is a schematic diagram showing an example of plan view of the flexible cable used in the contact assembly of the present invention.

FIGS. 6A and 6B are schematic diagrams showing examples of cross sectional view for connecting the flexible cable to the contactor and the probe card in the contact structure of the present invention.

FIG. 7 is a schematic diagram showing a further example of cross sectional view for connecting the flexible cable to the contactor and the probe card in the contact structure of the present invention.

FIG. 8 is a perspective view showing an example of detailed structure of the flexible cable and connection mechanism for connecting the flexible cable to the contactors and the sockets used in the present invention.

FIG. 9 is a schematic cross sectional view showing a further example of structure for connecting the flexible cable to the contactors and the probe card in the contact structure of the present invention.

FIG. 10 is a schematic cross sectional view showing a further example of structure for connecting the flexible cable to the contactors and the probe card in the contact structure of the present invention.

FIG. 11 is a schematic diagram showing a cross sectional view of another example of a probe contact assembly using the contact structure of the present invention for interfacing between the semiconductor device under test and the test head of the semiconductor test system.

FIG. 12 is a schematic diagram showing a cross sectional view of a further example of structure for connecting the flexible cable to the contactors and the probe card in the contact structure of the present invention.

FIG. 13 is a schematic diagram showing a cross sectional view of an example of connection mechanism for connecting the flexible cable to the contactors in the contact structure of the present invention.

FIG. 14 is a schematic diagram showing a cross sectional view of an example of connection mechanism for connecting the flexible cable to the contactors in the contact structure of the present invention.

FIG. 15 is a schematic diagram showing a front view of the flexible cable and the contactors formed at the end of the flexible cable in the present invention.

FIG. 16 is a perspective view showing an example of detailed structure of the contactors formed on the flexible cable and the probe card in the present invention.

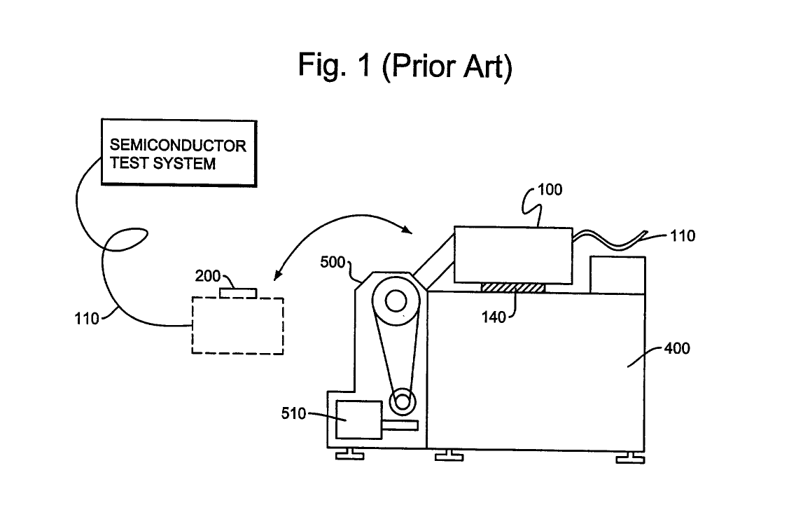

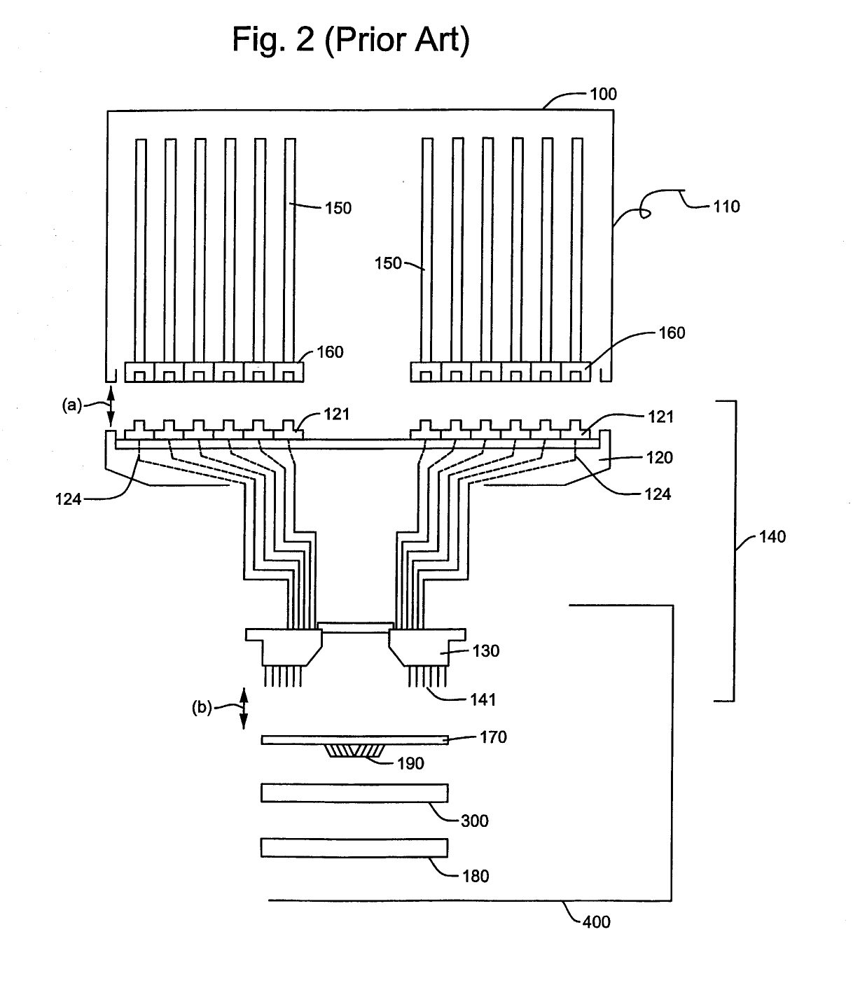

### DETAILED DESCRIPTION OF THE INVENTION

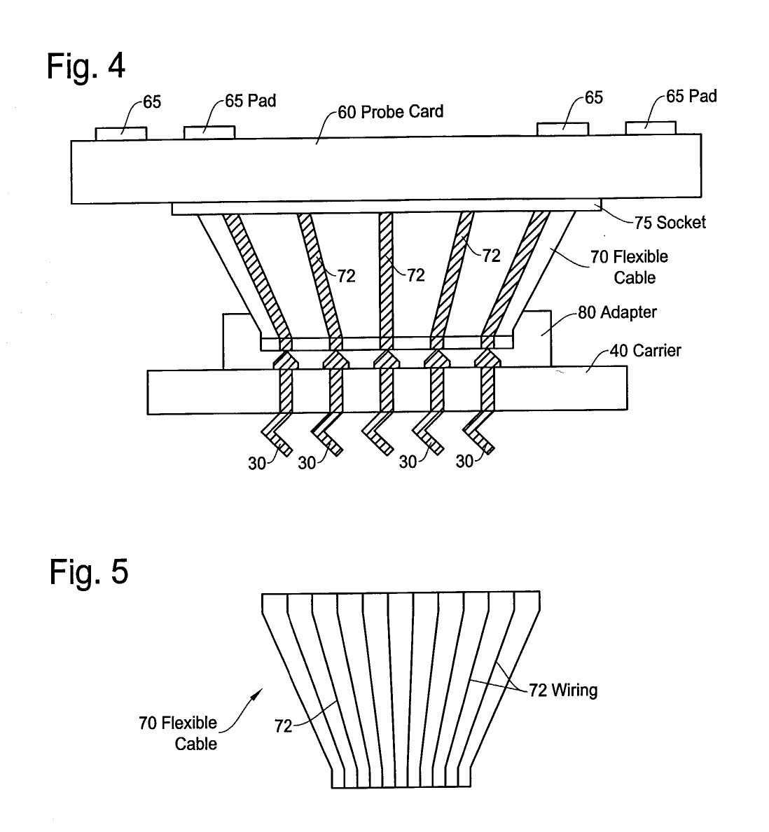

An example of contact structure and a probe contact assembly using such a contact structure in the present invention will be described with reference to FIGS. 4-16. Although the present invention will be described for the case of testing a semiconductor wafer, the contact structure of the present invention can also be used in testing LSI and VLSI chips, printed circuit boards and the like, and burn-in of semiconductor wafers and chips.

FIG. 4 is a cross sectional view of the contact structure of the present invention. The essential feature of the present invention is to use a flexible flat cable commonly available in the market for establishing the connection between the contactors and the probe card. In the example of FIG. 4, the contact structure is constituted by a flexible cable 70, a contactor carrier 40, contactors 30 mounted on the contactor carrier 40 and connected to the end of the flexible cable 70, and a probe card 60. Throughout this description of the invention, although not specifically shown, the probe card 60 and the contactor 40 are mechanically connected.

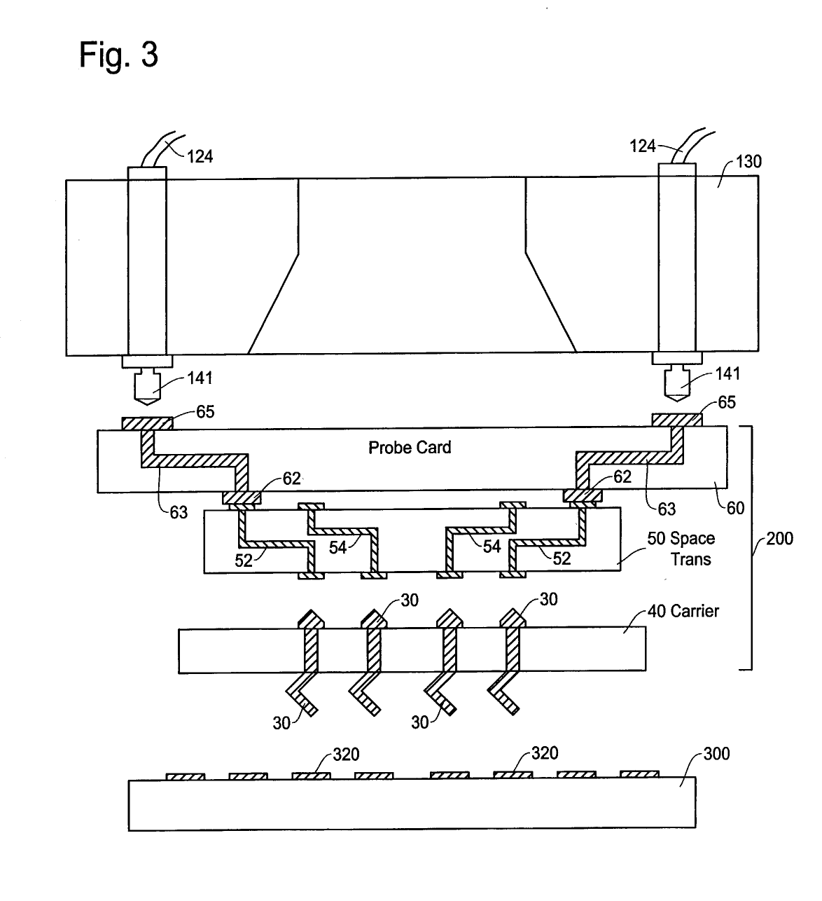

Contact pads (pogo-pin lands) 65 are provided on the probe card 60 to connect with the pogo-pins 141 (FIG. 3). The lower end of the flexible cable 70 is connected to the contactors 30 and the upper end of the flexible cable 70 is connected to the probe card 60. Thus, the contact structure of FIG. 4 is equivalent to the probe contact assembly of FIG. 3. However, in this example of FIG. 4, the contact substrate (space transformer) 20 shown in the conventional example of FIG. 3 is not used.

As shown in FIG. 5, the flexible cable 70 is a flat and flexible cable (flexible wiring board) typically made of polyimide, polyester or epoxy woven fiberglass. The flexible cable 70 is either single-sided or double-sided and typically covered by an insulation layer. The flexible cable 70 has a plurality of signal lines 72 made of conductive material such as nickel, copper or gold on the surface thereof or between two polyimide layers. As can be seen from the drawing, the flexible cable 70 has plurality of signal lines 72 whose pitch (space) between the lines at one end is increased toward the other end. That is, one end of the flexible cable 70 has the signal lines 72 close together in pitch (space) than the other end, therefore, achieving a fan-out of pitch without the use of the space transformer (FIG. 3).

The contactors 30 are mounted on the contactor carrier 40 and establishes electrical connection with the signal lines 72 at the appropriate end (with small pitch) of the flexible cable 70. The contactors 30 can be created by using the signal lines 72 of the flexible cable (such as shown in FIG. 14) or attaching the separately made contactors to the signal lines 72 on the flexible cable 70. In this example, the insulation layer at the end of the flexible cable 70 is removed so that the signal line 72 is exposed and connected to the contactors 30 through an adapter 80. Many other ways for connecting the flexible cable 70 and the contactors 30 are possible some of which will be discussed later. The other end of the flexible cable 70 is connected to the probe card 60 through a socket 75 formed on the probe card 60. Many other ways for connecting the flexible cable 70 and the probe card 60 are possible.

Although not shown in FIG. 4 or other drawings, signal patterns are formed on the probe card 60 to connect the sockets 75 and the contact pads 65 so as to establish a large number of signal paths between tips of the contactors 30 and the pogo-pins 141. In an example of semiconductor wafer testing, several hundreds or several thousands of contactors are mounted on the probe contact assembly. Therefore, a large number of such signal patterns corresponding to such contactors are formed on the probe card 60.

Each of the contactors 30 mounted on the contactor carrier 40 has a top contact portion projected from the top surface of the contactor carrier 40 and a spring portion and a bottom contact portion projected from the bottom surface of the contact carrier 40. A body portion of the contactor 30 is inserted in the through hole of the contactor carrier 40. The spring portion of the contactor 30 produces, when pressed against the contact targets such as contact pads 320 of the wafer 300 to be tested shown in FIG. 3, a resilient contact force, so that all contactors can contact the contact pads without fail. The resiliency of the contactors 30 also promotes a scrubbing effect that occurs at the contacts in which the oxide layer is pierced through by the contactors to promote high connection performance.

In the conventional technology, fine pitch signal patterns have to be formed on the contact substrate (space transformer) 50 shown in FIG. 3 to fan-out the small pitch of contactors 30 to the pitches on the probe card 60. In the present invention, because of the flexible cables 70 which also functions to fan-out the pitch, the contact substrate (space transformer) 50 is no longer used or such fine patterns can be obviated from the contact substrate 50. This significantly contributes to the reduction of overall cost of the probe contact assembly.

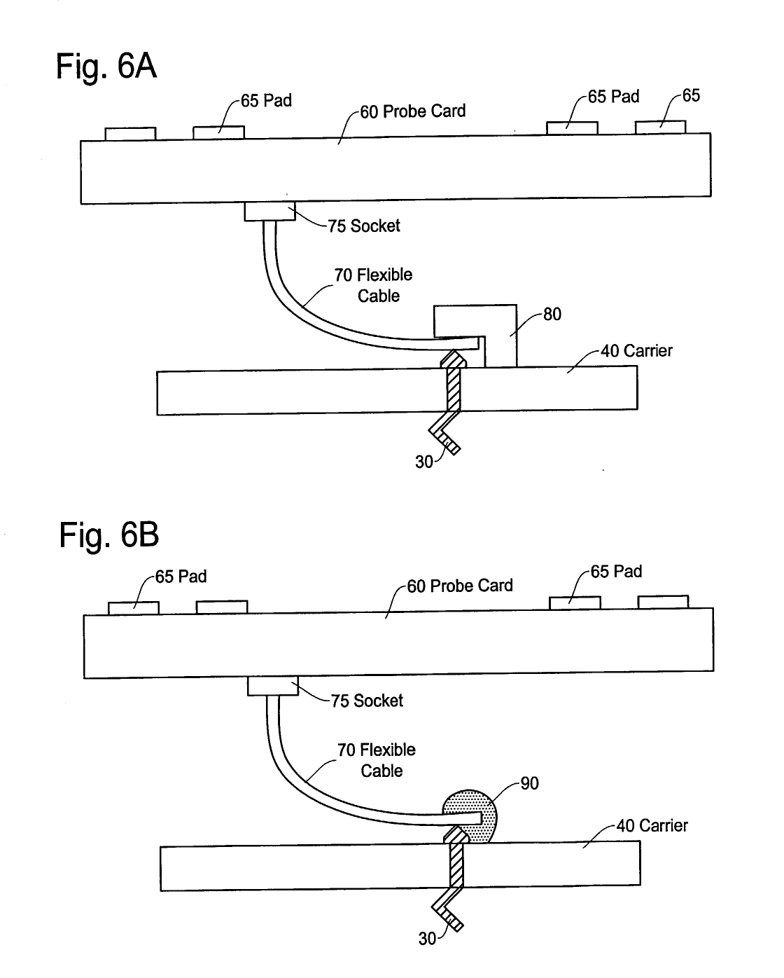

FIGS. 6A and 6B are cross sectional views showing example of structure for connecting the flexible cable to the contactor and the probe card in the contact structure of the present invention. In the example of FIG. 6, an adapter 80 that is mounted on the carrier 40 is used to attach the flexible cable 70 to the contactors 30. Thus, the top ends of the contactors 30 and the ends of the signal lines 72 of the flexible cable 70 establish electrical connection between them. In the example shown in FIG. 6B, an adapter is not utilized but instead an adhesive 90 connects the conducive signal lines 72 on the flexible cable 70 and the top ends of the contactor 30. This adhesive 90 can be of any adhering material as long as the contactors 30 and the signal lines 72 establish sufficient electrical connection. As an example, conductive adhesives can be used as the adhesive 90 to connect the contactors and the signal lines 72 of the flexible cable 70.

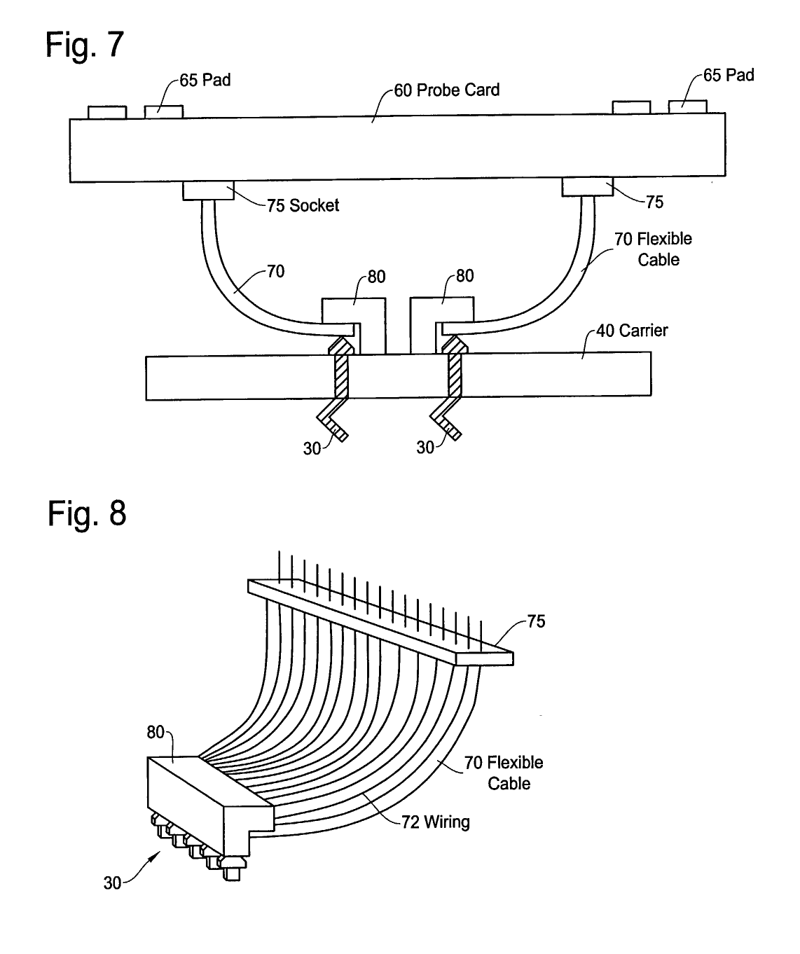

FIG. 7 is a diagram showing a cross sectional view of a further example of structure for connecting the flexible cable to the contactors and the probe card in the contact structure of the present invention. This example is essentially the same as the one shown in FIG. 6A but has two sets of flexible cable 70 and contactors 30. In the actual implementation of the present invention, hundreds of these connections are made using a large number of flexible cables 70 and the contactors 30 with the use of connection mechanism such as adapters 80 or adhesives 90 (FIG. 6B). As with the other examples, the sockets 75 are provided on the probe card 60 to make the connections between the flexible cables 70 and the probe card 60.

FIG. 8 is a perspective view showing an example of detailed structure of the flexible cable and the connection structure (adaptor) and the socket used in the present invention. As shown in FIG. 8, the end of the flexible cable 70 having the signal lines 72 with smaller pitch is connected to the top ends of the contactors 30 through the adaptor 80. As described above, the adaptor 80 can be replaced with any attachment means that is able to connect the signal lines 72 of the flexible cable 70 to the tips of the contactors 30. The another end of the flexible cable 70 is fanned-out so that the signal lines 72 with large pitch is attached to the socket 75 of the probe card 60. Although the connection of this end to the probe card is done using the socket 75 in this example, other connection means can be used as will be disclosed later. Further, only an abbreviated illustration is used in this example, many types of socket can be used in the implementation of the present invention.

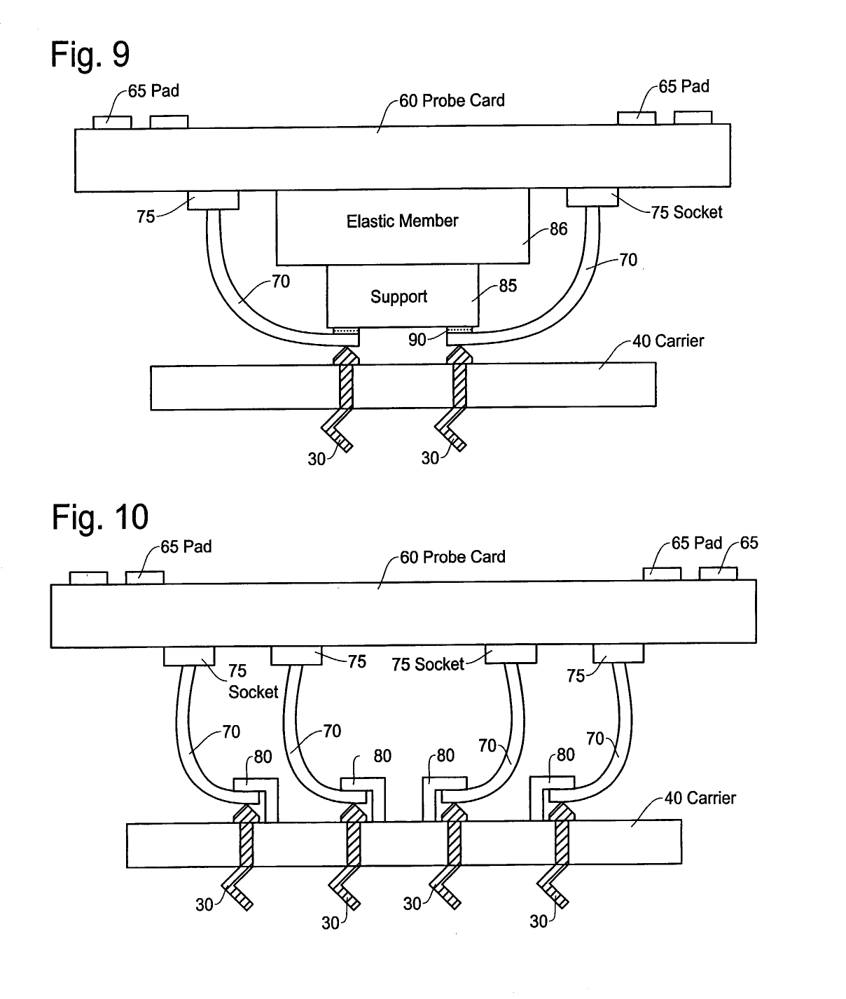

FIG. 9 is a diagram showing a cross sectional view of a further example of structure for connecting the flexible cable to the contactors and the probe card in the contact structure of the present invention. In the example of FIG. 9, the adapters in the foregoing examples are not used and instead, a support substrate 85 and an elastic member 86 are provided for connecting the flexible cable 70 to the contactors 30. The support substrate 85 and the elastic member 86 function to support and position the ends of the flexible cables 70.

The end of the flexible cable 70 to contact with the contactors 30 is mounted on the support substrate 85 using, for example, an adhesive 90. This adhesive 90 can be of any material that promotes sufficient mechanical connection between the support substrate 85 and the end of the flexible cable. The support substrate 85 can be made of various material such as silicon, glass epoxy, ceramic, glass, or the like. The elastic member 86 is provided between the support substrate 85 and the probe card 60 to provide a cushioning effect or flexibility to compensate small variations in the dimensions of the components incorporated in the contact structure. For example, unevenness in the length of the contactors 30 over the carrier 40 can be absorbed by the cushioning effect of the elastic member 86. An example of elastomer material is a synthetic rubber or plastic.

FIG. 10 is a diagram showing a cross sectional view of a further example of structure for connecting the flexible cable to the contactors and the probe card in the contact structure of the present invention. In this example, four sets of flexible cables 70 and contactors 30 are shown for an illustration purpose. As described with reference to FIG. 7 above, any number of flexible cables and contactors can be used in the present invention.

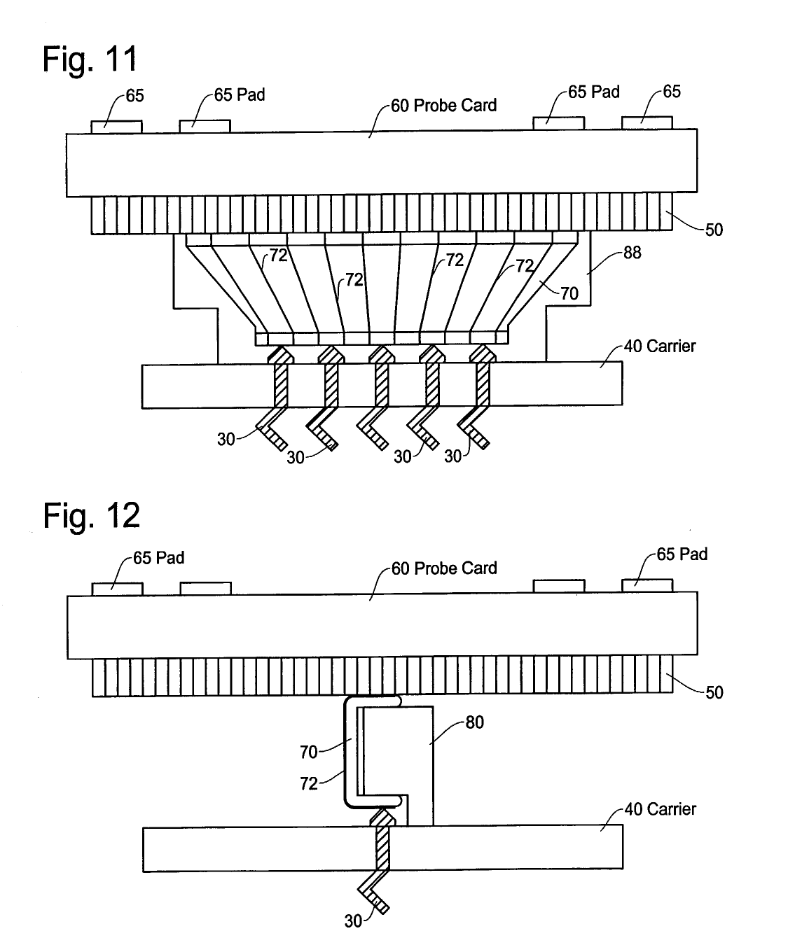

FIGS. 11 and 12 show another example of structure in the probe contact assembly using the contact structure of the present invention. FIG. 11 shows a cross sectional front view and FIG. 12 shows a cross sectional side view of the contact structure. Typically, the probe contact assembly is used for interfacing between the semiconductor device under test and the test head of the semiconductor test system. In the example of FIGS. 11 and 12, the contact structure is created by a flexible cable 70, a contactor carrier 40, contactors 30 mounted on the contactor carrier 40 and connected to the end (signal lines 72) of the flexible cable 70, a probe card 60, and a conductive elastomer 50. Contact pads (pogo-pin lands) 65 are provided on the probe card 60 to connect with the pogo-pins 141 (FIG. 3). As with the example of FIG. 4, the contact substrate (space transformer) 20 shown in the conventional example in FIG. 3 is not used.

The example of FIGS. 11 and 12 further includes an adapter 88 to support the flexible cable in such a way to connect the contactors 30 and the signal lines 72 of the flexible cable 70. In this example, the flexible cable 70 is a single sided type where the signal lines 72 are exposed at one side of the flexible cable. The adapter 88 preferably has a small degree of flexibility by being made of synthetic rubber of plastic, although the flexibility of adapter 88 is not essential to the present invention. The example of FIGS. 11 and 12 includes a conductive elastomer 50 provided between the flexible cable 70 and the probe card 60. By its elasticity, the conductive elastomer 50 is to ensure electrical communications between the signal lines 72 of the flexible cable 70 and the electrodes (not shown) located at the bottom surface of the probe card 60 by compensating unevenness or vertical gaps therebetween.

The conductive elastomer 50 is an elastic sheet with unidirectional conductivity by having a large number of conductive wires in a vertical direction. For example, the conductive elastomer 50 is comprised of a silicon rubber sheet and a multiple rows of metal filaments. The metal filaments (wires) are provided in the direction perpendicular to the horizontal sheet of the conductive elastomer 50. An example of pitch between the metal filaments is 0.02 mm with thickness of the silicon rubber sheet is 0.2 mm. Such a conductive elastomer is produced by Shin-Etsu Polymer Co. Ltd and available in the market.

As shown in the cross sectional side view of FIG. 12, the flexible cable 70 is bent around the adaptor 88 between the contactors 30 and the conductive elastomer 50 to establish communication between the contactors 30 and the probe card 60. As noted above, the flexible cable 70 is a single sided type which is provided with an insulation layer on only one side. This makes the connection between the contactor 30 and the signal line 72 of the flexible cable simple. By using the adaptor 88 shown in FIG. 12, an electrical connection can be made easily, since the signal lines 72 are exposed (as shown by bold line in FIG. 12). The adaptor 88 pressingly connects the one end of the flexible cable 70 to the tips of the contactor 30 and also pressingly connects the another end of the flexible cable 70 to the probe card 60 (conductive elastomer 50).

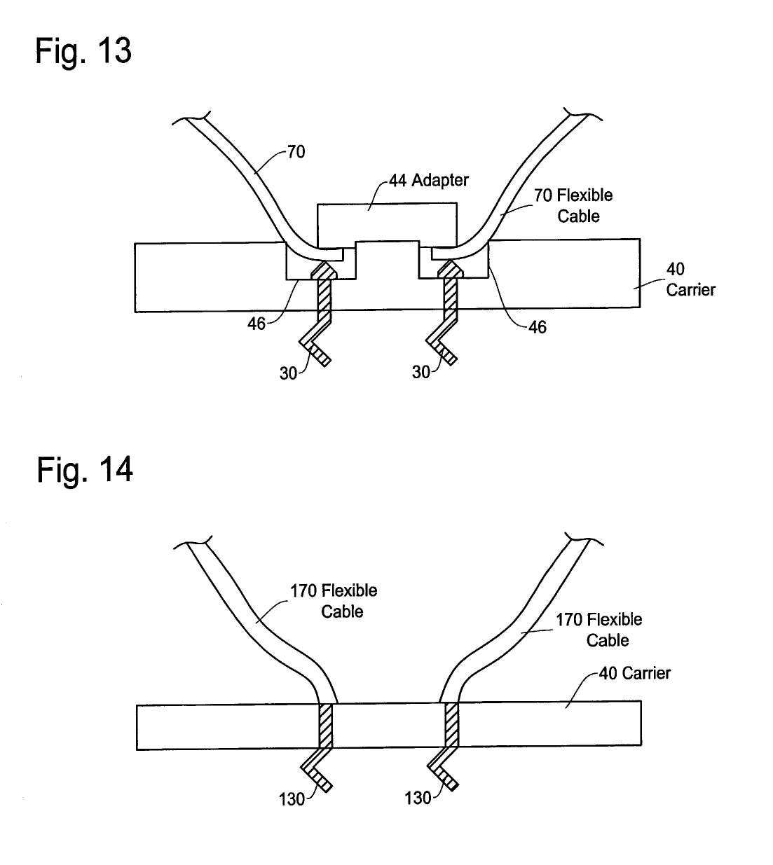

FIG. 13 is a diagram showing a cross sectional view showing an example of structure for connecting the flexible cable to the contactors in the contact structure of the present invention. In this example, the connection between the end of the flexible cable 70 and the contactors 30 is made through an adapter 44 mounted on the contactor carrier 40 and grooves 46 located at the connection points. By having the contactors 30 housed within the grooves 46, connection between the tips of the contactor 30 to the end of the flexible cable 70 can be made more secure. Furthermore, a single adaptor 44 can be used to bind two or more ends of the flexible cables.

FIG. 14 is a diagram showing a cross sectional view of another example of structure for connecting the flexible cable to the contactors in the contact structure of the present invention. In this example, the extension of the signal lines 72 of the flexible cable 70 is used as contactors 30. For example, the conductor at an end of the flexible cable 70 is exposed by removing the insulation material and inserted in the through holes of the contactor carrier 40. They are then bent to produce a spring portion so that a resilient contact force is produced there when it is pressed against the contact targets on the semiconductor wafer under test. Preferably, an adhesive is provided between the ends of the insulation layer of the flexible cable 70 and the surface of the contactor carrier 40.

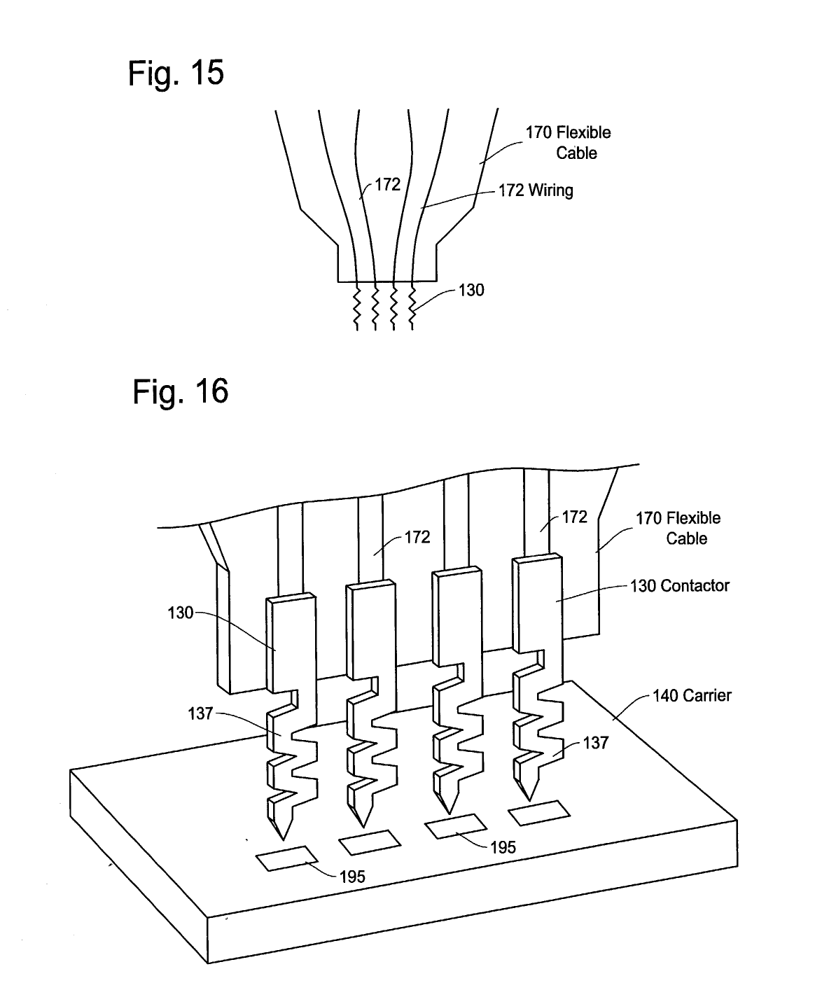

An example of front view of the flexible cable 170 is shown in a schematic diagram of FIG. 15 wherein a large number of conductor (signal lines) 172 are formed on a flat surface of the cable 170 with a fine pitch such as several ten to several hundred micrometers. As shown in FIG. 15, the space between the signal lines is increased toward the end opposite to the contactors 130, thereby functioning as the space transformer.

FIG. 16 is a perspective view showing an example of detailed structure of the contactors 130 formed on the flexible cable 170 to be mounted on the probe card 160. As shown in this example, each contactor 130 is connected to the corresponding signal line 172 at the end of the flexible cable 170. Preferably, the contactor 130 has a spring portion 137 to produce a resilient contact force when pressed against the contact target. In this example, the contactors 130 are produced separately and attached to the conductor (signal line) 172 on the flexible cable 170 to be inserted in through holes 195 on the contactor carrier 140. Each contactor 130 is flat as a whole and has a spring portion 137 which is zig-zag shaped or contains multiple number of bends to produce a spring force in a vertical direction when pressed against the contact target.

The contactors 136 can be produced through various methods, one example of which is disclosed in the U.S. Pat. Nos. 5,989,994 and 6,297,164 owned by the same assignee of the present invention. These patents provide an easy and reliable process for producing a large number of contactors of complicated shape at the same time with low cost. Basically, the contactors 130 are produced in a horizontal direction on a planar surface of a substrate such as a silicon substrate and removed from the silicon substrate to be attached to the flexible cable 170.

The contactors 130 are connected to the corresponding conductor 172 by means of, for example, conductive adhesive, solder reflow, or other means. When the contactors 130 are inserted in the through holes 195, the flexible cable 170 is preferably fixed to the contactor carrier through an adhesive or other means. Although not shown, at the end of the flexible cable 170, where the contactors 130 are connected, an enforcing means such as a rigid plate may be provided to improve the mechanical strength of this area.

Preferably, the tip of the contactor is sharpened to achieve a scrubbing effect for high contact performance. When the contactor tip is sharpened, and when pressed against the contact target, the contactor tip scrubs an oxide surface of the contact target, thereby directly contacting the conductive material of the contact target.

As has been foregoing, according to the present invention, the contact structure is created with use of flexible flat cables which are available in the market. The contactors are formed at one end of the flexible cable and are mounted on the contactor carrier. The flexible cable of the present invention contains multiple number of signal lines pitched close together at one end and pitched further apart at another end to fan-out the pitches of the contactors on the contactor carrier to match the pitches of the contact pads on the probe card. The contact structure of the present invention is low cost, reliable and yet achieves high performance. Since the flat cables connecting the contactors and the pads on the probe card enable to obviate either a space transformer (contact substrate) or fine pitch wiring patterns on the contact substrate in the conventional technology, the present invention also contributes to the overall cost reduction and design simplification in the probe contact assembly.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. A contact structure for establishing electrical connection with contact targets, comprising:
a probe card having a plurality contact pads;
a contactor carrier for mounting a plurality of contactors; and
a flexible cable having a plurality of signal lines for transmitting electrical signals therethrough;
wherein a first end of the flexible cable has a small pitch of the signal patterns while a second end of the flexible cable has a pitch of signal lines which is substantially larger than that of the first end; and
wherein the first end of the flexible cable is connected to the contactors and the second end of the flexible cable is connected to the probe card.

2. A contact structure for establishing electrical connection with contact targets as defined in claim 1, wherein each of the contactors is integrally formed with the flexible cable by conductor of the corresponding signal line on the flexible cable.

3. A contact structure for establishing electrical connection with contact targets as defined in claim 1, wherein the contactors are produced separately from the flexible cable and attached to the corresponding signal lines on the flexible cable.

4. A contact structure for establishing electrical connection with contact targets as defined in claim 1, further including a socket to connect the second end of the flexible cable to the probe card.

5. A contact structure for establishing electrical connection with contact targets as defined in claim 1, further including an adaptor mounted on the contactor carrier to connect the first end of the flexible cable to the plurality of contactors.

6. A contact structure for establishing electrical connection with contact targets as defined in claim 1, further including an adhesive to connect the first end of the flexible cable to the plurality of contactors.

7. A contact structure for establishing electrical connection with contact targets as defined in claim 1, wherein two or more flexible cables are connected between the probe card and the contactors.

8. A contact structure for establishing electrical connection with contact targets as defined in claim 1, further including a support member to support the first end of the flexible cable.

9. A contact structure for establishing electrical connection with contact targets as defined in claim 8, further including an elastic member between the probe card and the support member.

10. A contact structure for establishing electrical connection with contact targets as defined in claim 1, wherein each of the contactor includes a spring portion to produce a resilient contact force when the contact structure is pressed against the contact targets.

11. A contact structure for establishing electrical connection with contact targets, comprising:
a probe card having a plurality contact pads;
a contactor carrier for mounting a plurality of contactors; and
a flexible cable having a plurality of signal lines for transmitting electrical signals therethrough;
a conductive elastomer provided between the probe card and the flexible cable;
wherein a first end of the flexible cable has a small pitch of the signal patterns while a second end of the flexible cable has a pitch of signal lines which is substantially larger than that of the first end; and
wherein the first end of the flexible cable is connected to the contactors and the second end of the flexible cable is connected to the probe card.

12. A contact structure for establishing electrical connection with contact targets as defined in claim 11, wherein each of the contactors is integrally formed with the flexible cable by conductor of the corresponding signal line on the flexible cable.

13. A contact structure for establishing electrical connection with contact targets as defined in claim 11, wherein the contactors are produced separately from the flexible cable and attached to the corresponding signal lines on the flexible cable.

14. A contact structure for establishing electrical connection with contact targets as defined in claim 11, further including an adaptor between the probe card and the contactor carrier on which the flexible cable is bent around to electrically connect the first end of the flexible cable to the plurality of contactors and also to connect the second end of the flexible cable to the probe card through the conductive elastomer.

15. A contact structure for establishing electrical connection with contact targets as defined in claim 11, wherein two or more flexible cables are connected between the probe card and the contactors.

16. A contact structure for establishing electrical connection with contact targets as defined in claim 11, wherein each of the contactor includes a spring portion to produce a resilient contact force when the contact structure is pressed against the contact targets.

17. A contact structure for establishing electrical connection with contact targets as defined in claim 11, wherein the conductive elastomer is comprised of a silicon rubber sheet and metal filaments running in perpendicular to the rubber sheet so as to establish communication only in the vertical direction.
